(19) United States
(12) Patent Application Publication
(10) Pub. No.: US 2005/0070082 A1
(43) Pub. Date: Mar. 31, 2005

(54) Semiconductor device having a nickel/cobalt silicide region formed in a silicon region

(76) Inventors: Thorsten Kammler, Ottendorf-Okrilla (DE); Karsten Wieczorek, Dresden (DE); Austin Frenkel, San Jose, CA (US)

Correspondence Address: WILLIAMS, MORGAN & AMERSON, P.C., 10333 RICHMOND, SUITE 1100, HOUSTON, TX, 77042, US

(21) Appl. No.: 10/859,552

(22) Filed: Jun. 2, 2004

(30) Foreign Application Priority Data
Sep. 30, 2003 (DE) 103 45 374.1

(51) Int. Cl. H01L 21/4763

(52) U.S. Cl. 438/592; 438/305

(57) ABSTRACT

By forming a buried nickel silicide layer followed by a cobalt silicide layer in silicon-containing regions, such as a gate electrode of a field effect transistor, the superior characteristics of both silicides may be combined so as to provide the potential for further device scaling without unduly compromising the sheet resistance and the contact resistance of scaled silicon circuit features.

### BACKGROUND OF THE INVENTION

1. Field of the Invention

Generally, the present invention relates to the fabrication of integrated circuits, and, more particularly, to the formation of metal silicide regions on silicon-containing conductive circuit elements to decrease a sheet resistance thereof.

2. Description of the Related Art

In modern ultrahigh density integrated circuits, device features are steadily decreasing to enhance device performance and functionality of the circuit. Shrinking the feature sizes, however, entails certain problems that may partially offset the advantages obtained by reducing the feature sizes. Generally, reducing the size of, for example, a transistor element such as a MOS transistor, may lead to superior performance characteristics due to a decreased channel length of the transistor element, resulting in a higher drive current capability and enhanced switching speed. Upon decreasing the channel length of the transistor elements, however, the electrical resistance of conductive lines and contact regions, i.e., of regions that provide electrical contact to the periphery of the transistor elements, becomes a major issue since the cross-sectional area of these lines and regions is also reduced. The cross-sectional area, however, determines, in combination with the characteristics of the material comprising the conductive lines and contact regions, the effective electrical resistance thereof.

Moreover, a higher number of circuit elements per unit area also requires an increased number of interconnections between these circuit elements, wherein, commonly, the number of required interconnects increases in a non-linear manner with the number of circuit elements so that the available real estate for interconnects becomes even more limited.

The majority of integrated circuits are based on silicon, that is, most of the circuit elements contain silicon regions, in crystalline, polycrystalline and amorphous form, doped and undoped, which act as conductive areas. An illustrative example in this context is a gate electrode of a MOS transistor element, which may be considered as a polysilicon line. Upon application of an appropriate control voltage to the gate electrode, a conductive channel is formed at the interface of a thin gate insulation layer and an active region of the semiconducting substrate. Although reducing the feature size of a transistor element improves device performance due to the reduced channel length, the shrinkage of the gate electrode (in the gate length direction), however, may result in significant delays in the signal propagation along the gate electrode, i.e., the formation of the channel along the entire extension (in the gate width direction) of the gate electrode. The issue of signal propagation delay is even exacerbated for moderately elongated polysilicon lines connecting individual circuit elements or different chip regions. Therefore, it is extremely important to improve the sheet resistance of polysilicon lines and other silicon-containing contact regions to allow further device scaling without compromising device performance. For this reason, it has become standard practice to reduce the sheet resistance of polysilicon lines and silicon contact regions by forming a metal silicide in and on appropriate portions of the respective silicon-containing regions.

With reference to FIGS. 1a-1d, a typical prior art process flow for forming metal silicide on a corresponding portion of a MOS transistor element will now be described as an illustrative example for demonstrating the reduction of the sheet resistance of silicon.

FIG. 1a schematically shows a cross-sectional view of a transistor element 100, such as a MOS transistor, that is formed on a substrate 101 including a silicon-containing active region 102. The active region 102 is enclosed by an isolation structure 103, which in the present example is provided in the form of a shallow trench isolation usually used for sophisticated integrated circuits. Highly doped source and drain regions 104 including extension regions 105 are formed in the active region 102. The source and drain regions 104 including the extension regions 105 are laterally separated by a channel region 106. A gate insulation layer 107 electrically and physically isolates a gate electrode 108 from the under-lying channel region 106. Spacer elements 109 are formed on sidewalls of the gate electrode 108. A refractory metal layer 110 is formed over the transistor element 100 with a thickness required for further processing in forming metal silicide portions.

A typical conventional process flow for forming the transistor element 100, as shown in FIG. 1a, may include the following steps. After defining the active region 102 by forming the shallow trench isolations 103 by means of advanced photolithography and etch techniques, well-established and well-known implantation steps are carried out to create a desired dopant profile in the active region 102 and the channel region 106.

Subsequently, the gate insulation layer 107 and the gate electrode 108 are formed by sophisticated deposition, photolithography and anisotropic etch techniques to obtain a desired gate length, which is the horizontal extension of the gate electrode 108, i.e., in the plane of the drawing of FIG. 1a, as indicated by the double arrow 150. Thereafter, a first implant sequence may be carried out to form the extension regions 105 wherein, depending on design requirements, additional so-called halo implants may be performed.

Next, the spacer elements 109 are formed by depositing a dielectric material, such as silicon dioxide and/or silicon nitride, and patterning the dielectric material by an anisotropic etch process. Thereafter, a further implant process may be carried out to form the source and drain regions 104, followed by anneal cycles to activate the dopants and at least partially cure lattice damage created during the implantation cycles.

Subsequently, the refractory metal layer 110 is deposited on the transistor element 100 by, for example, chemical vapor deposition (CVD) or physical vapor deposition (PVD). Preferably, a refractory metal such as titanium, cobalt, nickel and the like is used for the metal layer 110. It turns out, however, that the characteristics of the various refractory metals during the formation of a metal silicide and afterwards in the form of a metal silicide significantly differ from each other. Consequently, selecting an appropriate metal depends on further design parameters of the transistor element 100 as well as on process requirements in following processes. For instance, titanium is frequently used for forming a metal silicide on the respective silicon-containing portions. However, the electrical properties of the resulting titanium silicide strongly depend on the dimensions of the transistor element 100. Titanium silicide tends to agglomerate at grain boundaries of polysilicon and therefore may increase the total electrical resistance, wherein this effect is pronounced with decreasing feature sizes so that the use of titanium may not be acceptable for polysilicon lines, such as the gate electrode 108 having a lateral dimension, i.e., a gate length, of 0.2 micrometers and less.

For circuit elements having feature sizes of this order of magnitude, cobalt is preferably used as a refractory metal, since cobalt does not substantially exhibit a tendency for blocking grain boundaries of the polysilicon. However, cobalt silicide may show a significant deterioration in view of its sheet resistance for extremely scaled devices as will be explained in more detail later on. Another candidate that is frequently used in forming a metal silicide is nickel, which, however, may result in a degraded contact resistance in combination with local interconnects. In order to discuss the characteristics of cobalt that has superior contact characteristics and is therefore currently the preferred material for silicides, it is now assumed that the metal layer 110 is comprised of cobalt so as to allow the formation of the transistor element 100 as a sophisticated device having a gate length much less than 0.2 μm.

A first anneal cycle is performed to initiate a reaction between the cobalt in the layer 110 and the silicon in the drain and source regions 104 and the polysilicon in the gate electrode 108. Optionally, a titanium nitride layer having a thickness in the range of approximately 10-20 nm may be deposited above the refractory metal layer 110 prior to annealing the substrate 101 to decrease the finally obtained sheet resistance of the cobalt disilicide by reducing an oxidation of cobalt in the subsequent anneal cycles. Typically, the anneal temperature may range from approximately 450-550° C. to produce cobalt monosilicide. Thereafter, non-reacted cobalt is selectively etched away and then a second anneal cycle is performed with a higher temperature of approximately 700° C. to convert cobalt monosilicide into low-ohmic phase comprised of cobalt disilicide.

FIG. 1b schematically shows the transistor element 100 with cobalt disilicide regions 111 formed on the drain and source region 104 and a cobalt disilicide region 112 on the gate electrode 108. Although cobalt may successfully be used for feature sizes of approximately 0.2 μm and even less, it turns out that, for further device scaling, requiring a gate length of well less than 100 nm, the sheet resistance of the cobalt disilicide enhanced gate electrode 108 increases more rapidly than would be expected by merely taking into account the reduced feature size of the gate electrode 108. It is believed that the increase of the resistivity of the region 112 is caused by tensile stress between individual cobalt disilicide grains, thereby significantly affecting the film integrity of the cobalt disilicide when the gate length is on the order of magnitude of a single grain.

FIG. 1c schematically shows the transistor element 100 with a reduced gate length 150A of approximately 50-80 nm after completion of the above-described silicide formation process. Irregularities 112A in the form of, for instance, voids and interruptions in the cobalt disilicide region 112 of the gate electrode 108 may occur and cause a significant increase of the sheet resistance.

FIGS. 1d and 1e schematically represent a top view of the gate electrodes 108 having a gate length 150 of approximately 200 nm compared to the gate length 150A of approximately 50 nm. FIG. 1d depicts the gate electrode 108 with the gate length 150, containing a plurality of single grains 113 arranged along the length 150, whereas, as is shown in FIG. 1e, only one single grain 113 is formed across the length 150A. While the thermal stress induced during the second anneal cycle in converting cobalt monosilicide into cobalt disilicide may be compensated for by the plurality of grains across the length 150, the single grain formed across the length 150A may not allow efficient absorption of the stress and may cause the interruption 112A of the cobalt disilicide film. As a consequence, the sheet resistance of the polysilicon gate electrode is drastically increased, thereby preventing aggressive device scaling without unduly degrading the transistor performance.

In view of the above-explained problems, therefore, a need exists for an improved silicide formation technique, enabling further device scaling while not unduly compromising production yield.

### SUMMARY OF THE INVENTION

Generally, the present invention is directed to a technique that combines the advantages of a nickel silicide, i.e., a superior behavior in combination with an underlying silicon and the superior contact characteristics of cobalt silicide to provide the potential for further device scaling without unduly compromising the sheet resistance of a silicon feature including a metal silicide region. To this end, a layer of silicide that is substantially comprised of nickel silicide followed by a layer of metal silicide that is substantially comprised of cobalt silicide may be formed in a common formation process so that the problems occurring at a silicon cobalt silicide interface may be significantly reduced or even completely avoided.

According to one illustrative embodiment of the present invention, a method comprises forming a layer comprising metallic cobalt and metallic nickel over a silicon-containing region that is formed on a substrate. Thereafter, a heat treatment is performed with the substrate at a first temperature to allow nickel and cobalt to react with silicon to form a silicide in the silicon-containing region. Next, non-reacted nickel and cobalt are removed from the substrate and a further heat treatment is performed with the substrate at a second temperature that is higher than the first temperature to modify the silicide which has formed during the heat treatment at the first temperature.

According to a further illustrative embodiment of the present invention, a method of forming a field effect transistor comprises forming a polysilicon-containing gate electrode on a gate insulation layer that is formed above a substrate. A drain region and a source region are formed in a silicon-containing semiconductor region, wherein the drain and source regions are disposed adjacent to the gate electrode. Next, sidewall spacer elements are formed on sidewalls of the gate electrode and a layer comprising metallic cobalt and metallic nickel is formed over the gate electrode and the drain and source regions. Additionally, by means of the layer comprising the metallic cobalt and the metallic nickel, a region containing cobalt silicide and nickel silicide is formed at least in the gate electrode.

In accordance with yet another illustrative embodiment of the present invention, a method of forming a field effect transistor comprises forming a layer stack, which includes at least a gate insulation layer, a polysilicon layer, and a cap layer above a silicon region formed on a substrate. The layer stack is patterned so as to form a gate electrode having a top surface that is covered by at least the cap layer. Moreover, a drain region and a source region are formed adjacent to the gate electrode, and silicide regions comprising a first metal are formed in the drain and source regions. Furthermore, the top surface of the gate electrode is exposed and a nickel silicide/cobalt silicide layer stack region is formed in the gate electrode.

According to another illustrative embodiment of the present invention, a field effect transistor comprises a silicon gate electrode formed on a gate insulation layer. The transistor further comprises a drain region and a source region formed adjacent to the gate electrode. Additionally, a nickel silicide region is formed on the silicon gate electrode and a cobalt silicide region is formed above the nickel silicide region.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically show cross-sectional views of a conventional field effect transistor during different stages of manufacture;

FIGS. 1d-1e schematically show top views of gate electrodes of different gate lengths, wherein an unduly increased gate resistance may be observed at a gate length of less than 100 nm; and

FIGS. 2a-2d schematically show cross-sectional views of a field effect transistor during varying manufacturing stages in accordance with illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

It should be noted that the present invention is particularly advantageous when applied to the formation of field effect transistors of extremely reduced feature sizes, as the problems associated with cobalt silicide at feature sizes of well below 100 nm may be significantly reduced or avoided by providing a stacked nickel silicide/cobalt silicide region. The nickel silicide formed adjacent to the silicon allows a reduction of line width without unduly compromising the silicide film characteristics, whereas cobalt silicide is an approved and well-established silicide material providing superior contact resistance to other contact materials such as tungsten and the like, thereby providing a high degree of compatibility with standard CMOS process techniques. However, the present invention should not be considered as being restricted to critical dimensions of 100 nm and less unless such restrictions are explicitly set forth in the appended claims.

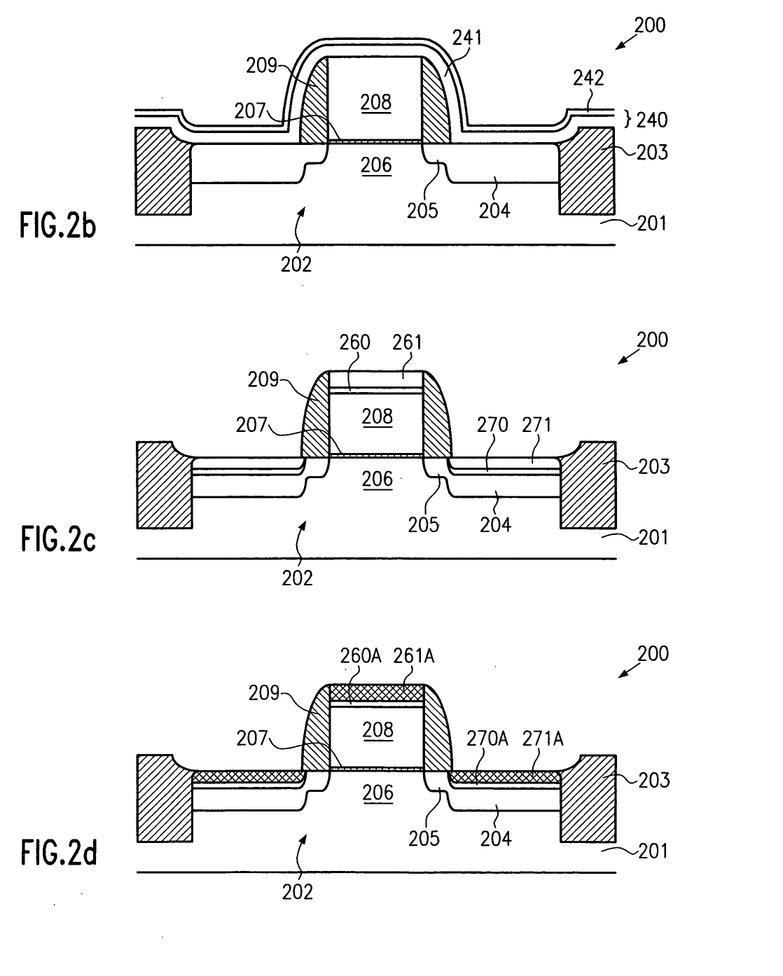

With reference to FIGS. 2a-2d, further illustrative embodiments of the present invention will now be described in more detail. In FIG. 2a, a field effect transistor 200 is illustrated so as to represent any silicon-containing region which is intended to receive a silicide portion so as to reduce the sheet resistance thereof. As previously explained, gate electrodes, drain and source regions, polysilicon lines and the like need to be modified in terms of their conductivity, especially as the critical dimensions of these silicon features are steadily reduced to a size of 50 nm and even less currently. Unless otherwise specified in the appended claims, the field effect transistor 200 is to be considered as representative of any silicon-containing circuit feature requiring the formation therein of a metal silicide region. The field effect transistor 200 comprises a substrate 201, which may be any appropriate substrate, such as a silicon wafer, a silicon-on-insulator (SOI) substrate, and the like. A transistor active region 202 is formed in the substrate 201 and the dimensions thereof are defined by an isolation structure 203, which may be provided in the form of a trench isolation structure. Highly doped drain and source regions 204 including respective extension regions 205 are formed in the active region 202 and are separated from each other by a channel region 206. A polysilicon gate electrode 208 is formed above the channel region 206 and is separated therefrom by a gate insulation layer 207. Moreover, sidewall spacer elements 209 are formed on sidewalls of the polysilicon gate electrode 208. In one embodiment, as shown in FIG. 2a, a cap layer 230 may be located above the gate electrode 208 so as to cover a top surface of the gate electrode 208. The cap layer 230 may be comprised of silicon nitride, silicon dioxide, silicon oxynitride, and the like, and may advantageously be comprised of a material exhibiting optical characteristics that enable the cap layer 230 to be used as a bottom anti-reflective coating during the patterning of the gate electrode 208.

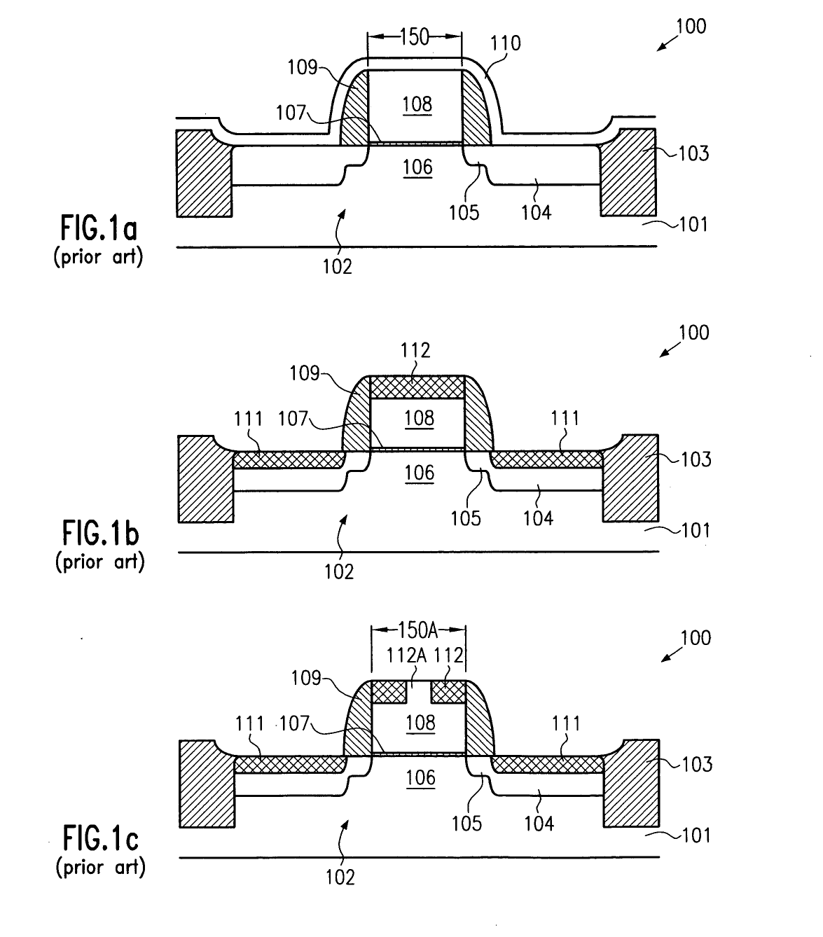

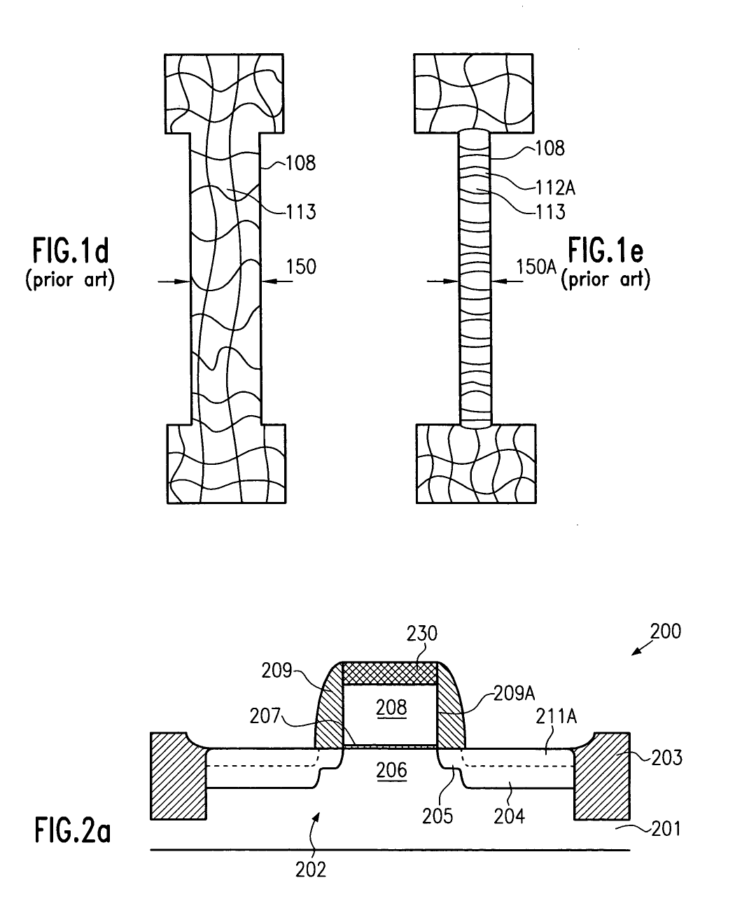

A typical process flow for forming the field effect transistor 200 as shown in FIG. 2a may comprise substantially the same process as previously described with reference to FIG. 1a. Regarding the embodiment of the field effect transistor 200 including the cap layer 230, it is to be noted that, during the patterning of the gate electrode 208 by means of sophisticated photolithography, a bottom anti-reflective coating is used that is typically removed after the patterning process. In some embodiments of the present invention, contrary to the conventional process flow, the bottom anti-reflective coating may be preserved as the cap layer 230. The cap layer 230 provides the possibility of independently forming metal silicide regions in the drain and source regions 204 on the one hand, and, after completion of the metal silicides in the drain and source regions 204 in the gate electrode 208, subsequently removing the cap layer 230 and performing a process sequence on the other hand, as will be described with reference to FIGS. 2b-2d. That is, in some embodiments, for instance, a cobalt silicide region may be formed in the drain and source regions 204, wherein substantially the same process sequence may be performed as is previously described with reference to FIGS. 1a-1c, wherein, however, the cap layer 230 prevents formation of cobalt silicide in the gate electrode 208. Thus, applying the process sequence described in FIGS. 1a-1c to the field effect transistor 200 having the cap layer 230 results in the formation of cobalt silicide regions 211a, indicated by dashed lines. Thereafter, the cap layer 230 may be removed for forming a nickel silicide/cobalt silicide region in the gate electrode 208. For convenience, in the further description it is now referred to as the field effect transistor 200 lacking the cap layer 230, since essentially the same process steps may be applied to the transistor 200 as shown in FIG. 2a, thereby forming a nickel silicide/cobalt silicide region in the gate electrode 208 only.

FIG. 2b schematically shows the field effect transistor 200 with a metal layer 240 formed thereon, wherein the metal layer 240 comprises metallic cobalt and metallic nickel. In one particular embodiment, the metal layer 240 may comprise a first sublayer 241 and a second sublayer 242, wherein the first sublayer 241 comprises cobalt and the second sublayer 242 comprises nickel. In other embodiments, the first sublayer 241 may be comprised of nickel and the second sublayer 242 may be comprised of cobalt. In one illustrative embodiment, the metal layer 240 may be provided as a substantially continuous layer comprised of a mixture of metallic cobalt and metallic nickel.

The metal layer 240 may be formed by chemical vapor deposition and/or physical vapor deposition. For instance, when the metal layer 240 comprises at least the two sublayers 241, 242, these sublayers may be individually deposited by a specific deposition process, such as a CVD process or a PVD process. In other embodiments, when the metal layer 240 is provided in the form of a mixture of metallic cobalt and metallic nickel, a common deposition process may be performed, for instance by commonly sputtering cobalt and nickel onto the field effect transistor 200. During the deposition process, irrespective of the type of deposition process, the ratio of cobalt to nickel may be controlled, for instance by controlling the layer thicknesses of the sublayers 241 and 242, or by controlling sputter process parameters when cobalt and nickel are deposited in a common process. In one particular embodiment, the deposition process is controlled such that the amount of cobalt, in terms of volume percentages, is higher than the amount of nickel. For instance, to this end, in one embodiment, the respective sublayer 241, 242 including the cobalt may be selected to be greater than the corresponding thickness of the other sublayer 241, 242, including the metallic nickel. For example, a thickness of the sublayer 241, for instance comprised of cobalt, may be selected in a range of approximately 10-50 nm, whereas the thickness of the sublayer 242, for instance comprised of nickel, may be selected in a range of approximately 10-30 nm. If, however, other ratios and/or layer thicknesses of the finally obtained nickel silicide and cobalt silicide are required, the corresponding thicknesses of the sublayers 241, 242 may correspondingly be adapted. The same holds true for the case when the metal layer 240 is provided in a substantially continuous manner, wherein the ratio of cobalt and nickel and the thickness of the continuous layer 240 determine the finally obtained nickel silicide and cobalt silicide thicknesses and their ratio.

Thereafter, a heat treatment is performed, such as a rapid thermal anneal process, at moderately low temperatures compared to a conventional cobalt silicidation process, as is described with reference to FIG. 1a. For instance, a temperature in the range of approximately 300-308° C. may be applied for a time interval of approximately 20-60 seconds so as to initiate metal diffusion and the formation of silicides with the underlying silicon. In one particular embodiment, an arrangement with the first sublayer 241 comprised of cobalt and the second sublayer 242 comprised of nickel surprisingly results in the formation of nickel silicide immediately on the underlying silicon, for instance on the silicon gate electrode 208 and the drain and source regions 204, unless not covered by the previously formed metal silicide 211a (see FIG. 2a). Without restricting the present invention to the following explanation, it is believed that the moderate temperature during the heat treatment creates a significantly higher diffusion activity of the nickel compared to the cobalt so that at an initial phase nickel penetrates into the cobalt, while the reduced temperature significantly slows down a reaction of cobalt with the underlying silicon. During the progress of the heat treatment, nickel increasingly diffuses into silicon and readily forms silicon silicide while the cobalt silicide formation is still significantly lower. Finally, a nickel silicide layer is formed on the underlying silicon, such as the gate electrode 208 and the drain and source regions 204, followed by a cobalt silicide layer.

FIG. 2c schematically shows the field effect transistor 200 after completion of the heat treatment as described above, thereby forming a nickel silicide layer 260 and above thereof a cobalt silicide layer 261. Similarly, a nickel silicide layer 270 may be formed in the drain and source regions 204 followed by a cobalt silicide layer 271. In case the field effect transistor comprises a metal silicide region 211a, for example in the form of a cobalt silicide, the formation of the nickel silicide layer 271 and of the cobalt silicide layer 270 may be substantially avoided or at least significantly be reduced so that, in this case, the formation process for the nickel silicide 260 and the cobalt silicide 261 in the gate electrode 208 may be specifically tailored so as to meet the requirements especially for an optimum conductivity of the gate electrode 208. On the other hand, when the metal silicide regions 211a (see Figure 2a) have previously been formed by means of the cap layer 230, the process parameters involved in forming the metal silicide regions 211a may be specifically designed so as to optimize these regions in view of junction depth and the like. After the completion of the heat treatment for forming the silicide layers 260, 261, 270, 271, any non-reacted metal may be removed from the sidewall spacers 209 and the isolation structure 203 by a selective wet chemical etch process, as is well established in the art.

Thereafter, a second heat treatment is formed, for instance in the form of a rapid thermal anneal process, at a temperature that is higher than the temperature of the previous heat treatment. In some embodiments, the temperature is selected in a range of approximately 450-650° C., whereas, in other embodiments, the temperature range is selected from approximately 500-600° C. Moreover, the duration of the heat treatment is selected to be approximately 10-60 seconds. During this heat treatment, the conversion of the cobalt silicide in the regions 261 and 271 into a low ohmic cobalt disilicide is initiated. During this heat treatment, the nickel silicide may also be converted into a nickel disilicide which exhibits excellent interface characteristics with the underlying silicon and acts thereby as a “buffer” to the overlying cobalt disilicide, in this way significantly reducing or eliminating stress-induced irregularities of the cobalt disilicide layer when the gate length of the gate electrode 208 is on the order of magnitude of a single grain of cobalt disilicide, as previously explained with reference to FIGS. 1c-1e. By controlling at least one process parameter of the heat treatment, that is, the temperature and the duration, the process of transforming the monosilicides into disilicides may be adjusted. For instance, in view of the desired low sheet resistance, an optimum of the finally obtained conductivity may be determined on the basis of experiments, wherein, for a given thickness ratio of the nickel silicide layer 260 and the cobalt silicide layer 261, at least one process parameter of the heat treatment may be varied to identify the dependency of the finally obtained sheet resistance on this process parameter. These measurements may be performed for a plurality of different thickness ratios so as to establish a plurality of measurement data from which the process parameters of the heat treatment may be derived. A corresponding control of the heat treatment may be necessary since nickel disilicide may exhibit an increased resistance compared to nickel monosilicide, whereas cobalt silicide shows the opposite behavior.

FIG. 2d schematically shows the field effect transistor 200 after completion of the second heat treatment with a modified nickel silicide layer 260a, followed by a modified cobalt silicide layer 261a formed in the gate electrode 208, and with a modified nickel silicide layer 270a and a modified cobalt silicide layer 271a formed in the drain and source regions 204, unless these regions are not covered by the previously formed metal silicide region 211a (see FIG. 2a). Due to the combination of the superior characteristics of cobalt silicide in view of its resistance to a contact metal and the characteristics of nickel silicide with respect to an interface with an underlying silicon, a low overall sheet resistance may be obtained for the gate electrode 208, while at the same time the resistivity to local interconnects (not shown) formed during a further manufacturing step for the field effect transistor 200 is also maintained at a low level.

As a result, the present invention provides a technique that enables the formation of a buried nickel silicide layer on silicon-containing circuit features with a cobalt silicide layer formed on the buried nickel silicide layer, thereby preserving the excellent characteristics of cobalt silicide with respect to contact resistance, while significantly reducing or avoiding sheet resistant degradation caused by a cobalt silicide/silicon interface. The cobalt silicide layer and the buried nickel silicide layer may be formed in a common formation process, wherein the characteristics, such as the thickness of the individual silicide layers, the overall sheet resistance, and the morphology of the layers, may be controlled by deposition parameters, such as layer thickness and composition ratio, and by the process parameters of a heat treatment, respectively. Surprisingly, the formation of a cobalt layer followed by a nickel layer leads to a redistribution of these materials during the formation of respective silicides, so that, in some embodiments, undesired nickel diffusion during the silicidation process may be reduced.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a layer comprising metallic cobalt and metallic nickel over a silicon-containing region formed on a substrate;
heat treating said substrate at a first temperature to allow nickel and cobalt to react with silicon to form a silicide in said silicon-containing region;
selectively removing non-reacted nickel and cobalt from said substrate; and
heat treating said substrate at a second temperature higher than said first temperature to modify said silicide formed during said heat treating at said first temperature.

2. The method of claim 1, wherein said layer comprising metallic cobalt and metallic nickel is formed by depositing a layer of metallic cobalt above said silicon-containing region and depositing a layer of metallic nickel above said layer of metallic cobalt.

3. The method of claim 1, wherein said layer comprising metallic cobalt and metallic nickel is formed by depositing a layer of metallic nickel above said silicon-containing region and depositing a layer of metallic cobalt above said layer of metallic nickel.

4. The method of claim 1, further comprising controlling a thickness of modified silicide formed in said silicon-containing region by adjusting a thickness of said layer.

5. The method of claim 4, wherein the thickness of said layer is adjusted by depositing a first layer comprised of metallic cobalt with a predefined first thickness and a second layer comprised of metallic nickel with a predefined second thickness.

6. The method of claim 5, wherein said second thickness is less than said first thickness.

7. The method of claim 1, further comprising controlling at least one of a temperature and a duration of the heat treatment for modifying the silicide to adjust an amount of cobalt disilicide in said silicon-containing region.

8. The method of claim 1, wherein said silicon-containing region comprises a polysilicon line having a lateral dimension that is less than approximately 100 nm.

9. The method of claim 1, wherein said silicon-containing region comprises a drain and a source region of a field effect transistor.

10. The method of claim 1, wherein said silicon-containing region includes a first portion and a second portion and wherein the method further comprises forming a metal silicide over said first portion prior to forming said layer comprising metallic cobalt and metallic nickel.

11. The method of claim 10, wherein said first portion comprises a drain region and a source region of a field effect transistor.

12. The method of claim 11, wherein said second portion comprises a gate electrode of said field effect transistor covered by sidewall spacer elements and a cap layer and wherein said method further comprises removing said cap layer prior to forming said layer comprising metallic cobalt and metallic nickel.

13. The method of claim 12, wherein a gate length of said gate electrode is approximately 50 nm or less.

14. A method of forming a field effect transistor, the method comprising:
forming a polysilicon containing gate electrode on a gate insulation layer formed above a substrate;
forming a drain region and a source region in a silicon-containing semiconductor area, said drain and source regions being disposed adjacent to the said electrode;
forming sidewall spacer elements on sidewalls of said gate electrode;
forming a layer comprising metallic cobalt and metallic nickel over said gate electrode and said drain and source regions; and
forming with said layer a cobalt silicide and nickel silicide containing region at least in said gate electrode.

15. The method of claim 14, wherein forming said cobalt silicide and nickel silicide containing region comprises:
heat treating said substrate at a first temperature to allow nickel and cobalt to react with silicon to form a silicide at least in said gate electrode;
selectively removing non-reacted nickel and cobalt from said substrate; and
heat treating said substrate at a second temperature higher than said first temperature to modify said silicide formed during said heat treating at said first temperature.

16. The method of claim 14, wherein said layer comprising metallic cobalt and metallic nickel is formed by depositing a first layer comprising metallic cobalt over said gate electrode and said drain and source regions and depositing a second layer comprising metallic nickel above said first layer.

17. The method of claim 14, wherein said layer comprising metallic cobalt and metallic nickel is formed by depositing a first layer comprising metallic nickel over said gate electrode and said drain and source regions and depositing a second layer comprising metallic cobalt above said first layer.

18. A method of forming a field effect transistor, the method comprising:
forming a layer stack including at least a gate insulation layer, a polysilicon layer and a cap layer above a silicon region formed on a substrate;
patterning said layer stack to form a gate electrode having a top surface covered by at least said cap layer;
forming a drain and a source region adjacent to said gate electrode;
forming silicide regions comprising a first metal in said drain and source regions;
exposing said top surface of said gate electrode; and
forming a nickel silicide/cobalt silicide layer stack region in said gate electrode.

19. The method of claim 18, wherein forming said nickel silicide/cobalt silicide layer stack region comprises:
forming a layer comprising metallic cobalt and metallic nickel;
heat treating said substrate at a first temperature to allow nickel and cobalt to react with silicon to form a silicide in said gate electrode;
selectively removing non-reacted nickel and cobalt from said substrate; and
heat treating said substrate at a second temperature higher than said first temperature to modify said silicide formed during said heat treating at said first temperature.

20. The method of claim 19, wherein said layer comprising metallic cobalt and metallic nickel is formed by depositing a first layer comprising metallic cobalt over said gate electrode and depositing a second layer comprising metallic nickel above said first layer.

21. The method of claim 19, wherein said layer comprising metallic cobalt and metallic nickel is formed by depositing a first layer comprising metallic nickel over said gate electrode and depositing a second layer comprising metallic cobalt above said first layer.

22. The method of claim 18, wherein said first metal is comprised of cobalt.

23. A field effect transistor, comprising:
a silicon gate electrode formed on a gate insulation layer;
a drain region and a source region formed adjacent to said gate electrode;
a nickel silicide region formed on said silicon gate electrode; and
a cobalt silicide region formed above said nickel silicide region.

24. The field effect transistor of claim 23, further comprising a cobalt silicide region formed in said drain and source regions.

25. The field effect transistor of claim 23, further comprising in said drain and source regions a second cobalt silicide region that is formed above a second nickel silicide region.

26. The field effect transistor of claim 23, wherein a thickness of said nickel silicide region is less than a thickness of said cobalt silicide region.
